(19) United States
(12) Patent Application Publication
(10) Pub. No.: US 2011/0019801 A1
(43) Pub. Date: Jan. 27, 2011

(54) METHOD FOR PRODUCING A 2D COLLIMATOR ELEMENT FOR A RADIATION DETECTOR AND 2D COLLIMATOR ELEMENT

(76) Inventors: Mario Eichenseer, Pinzberg (DE); Michael Miess, Baiersdorf (DE); Daniel Niederlöhner, Erlangen (DE); Stefan Wirth, Erlangen (DE)

Correspondence Address: HARNESS, DICKEY & PIERCE, P.L.C., P.O.BOX 8910, RESTON, VA, 20195, US

(21) Appl. No.: 12/838,660

(22) Filed: Jul. 19, 2010

(30) Foreign Application Priority Data
Jul. 22, 2009 (DE) 10 2009 034 208.7
Mar. 16, 2010 (DE) 10 2010 011 581.9

(51) Int. Cl. G21K 1/02; H05K 13/00

(52) U.S. Cl. 378/147; 29/592.1

(57) ABSTRACT

A method is disclosed for producing a 2D collimator element for a radiation detector, in which crossing webs made of a radiation-absorbing material are formed, layer-by-layer, by way of a rapid manufacturing technique. In at least one embodiment, the webs are aligned along a φ- and a z-direction and form a cell-shaped structure with laterally enclosed radiation channels, at least in the inner region of the 2D collimator element. In at least one embodiment, the invention moreover relates to a 2D collimator element for a radiation detector that has such a layered construction. This allows the provision of a very precise and rigid collimator arrangement which, at the same time, has a high collimation effect.

### PRIORITY STATEMENT

The present application hereby claims priority under 35 U.S.C. §119 on German patent application numbers DE 10 2009 034 208.7 filed Jul. 22, 2009 and DE 10 2010 011 581.9 filed Mar. 16, 2010, the entire contents of each of which are hereby incorporated herein by reference.

### FIELD

At least one embodiment of the invention generally relates to a method for producing a 2D collimator element for a radiation detector and to a 2D collimator element.

### BACKGROUND

By way of example, collimators are used in imaging with an X-ray scanner, e.g. a computed tomography scanner for examining a patient. The computed tomography scanner has, arranged on a gantry, an X-ray system with an X-ray source and an X-ray detector. The X-ray detector is generally constructed from a multiplicity of detector modules, which are lined-up next to one another in a linear or two-dimensional fashion. Each detector module in the X-ray detector for example comprises a scintillator array and a photodiode array, which are aligned with respect to one another. The elements in the scintillator array and in the photodiode array aligned with respect to one another form the detector elements of the detector module. The X-ray radiation incident on the scintillator array is converted into light, which is converted into electrical signals by the photodiode array. The electrical signals form the starting point of the reconstruction of an image of an object or patient examined using the computed tomography scanner.

The X-ray radiation emitted by the X-ray source is scattered in the object and so scattered radiation, so-called secondary radiation, also impinges on the X-ray detector in addition to the primary radiation from the X-ray source. This scattered radiation causes noise in the X-ray image and therefore reduces the recognizability of the contrast differences in the X-ray image. An X-ray-absorbing collimator is arranged over each scintillator array in order to reduce the influence of scattered radiation, and it only allows X-ray radiation from a certain spatial direction to reach the scintillator array. This can reduce image artifacts and, for a given contrast to noise ratio, significantly reduce the X-ray dose applied to a patient.

Previously, so-called 1D collimators were mainly used in a computed tomography scanner, which collimators are constructed from a multiplicity of collimator sheets arranged in succession in the φ-direction. Here, the collimator sheets are aligned with respect to the X-ray focus and allow a suppression of scattered radiation in the φ-direction, i.e. in the rotational direction of the gantry. The collimator sheets are produced from tungsten and have to be integrally connected to a support mechanism for mechanical stabilization.

There is also need for additional collimation in the z-direction if the X-ray detector is enlarged in the z-direction, i.e. in the direction of the patient axis, or in the case of dual-source systems, in which two recording systems, arranged in a measuring plane offset from another by a fixed angle in the φ-direction, are operated simultaneously for registering projections.

Such a two-dimensional collimator, abbreviated 2D collimator, is described in e.g. U.S. Pat. No. 7,362,894 B2 or in DE 10 2005 044 650 A1, the entire contents of each of which are hereby incorporated herein by reference. Here, as the width of the detector increases, it becomes increasingly more difficult to produce the grid-like support mechanism with sufficient precision and stability in order to hold the sheets in position. Additionally, a production method is known for achieving high precision and stability in a 2D collimator, in which a polymer compound with a metal component is cured in a grid-like two-dimensional mold. However, the disadvantage of this is that the collimation effect of the manufactured webs is significantly reduced due to the limited metal filler content of the compound, which is typically at 50%. Using this as a starting point, the invention is based on the object of developing a method for producing a 2D collimator element such that a produced 2D collimator element has high precision and stability, and that the conditions for a large reduction in scattered radiation are created. Moreover, it is an object of the invention to develop a 2D collimator element such that it has the aforementioned properties.

### SUMMARY

In at least one embodiment of the invention, a method is disclosed for producing a 2D collimator element for a radiation detector. Advantageous refinements of the invention are in each case the subject matter of the dependent claims.

In the method according to at least one embodiment of the invention for producing a 2D collimator element for a radiation detector, crossing webs made of a radiation-absorbing material are formed, layer-by-layer, by way of a rapid manufacturing technique, which webs are aligned along a φ- and a z-direction and form a cell-shaped structure with laterally enclosed radiation channels, at least in the inner region of the 2D collimator element.

The so-called rapid manufacturing technique is a quick production method, in which a component is constructed layer-by-layer from powdery material using physical and/or chemical effects. In each production step, a new layer can be applied selectively, very precisely and thinly onto the existing structure, and so the webs of the 2D collimator element can be produced very precisely in respect of their width, height and position. The production is brought about in this case on the basis of slice data that can easily be generated directly from 3D surface data, as is present in CAD systems. The 2D collimator element produced in this fashion is an integral component and not an assembly of a plurality of individual sheets. It therefore has a particularly high stability.

A metallic powder, which has not had a binding agent added thereto, is preferably used as radiation-absorbing material, and so the metal filler content of the webs is almost 100% and very effective collimation can be obtained.

Selective laser melting (SLM) is preferably used as rapid manufacturing technique. In this technique the 2D collimator element is constructed in three dimensions according to the layer-construction principle by irradiating individual layers by a laser, e.g. a fiber laser, with a laser power of approximately 100 to 1000 Watt. The good focusability of the laser radiation allows selective limitation of the laser sintering process to small areas, and so very fine webs of the order of between 50 and 300 μm, preferably 80 μm, can also be produced. As a result of a fast deflection of a laser beam being possible, the production time can be significantly reduced compared to know production process in which polymer compounds are cured.

In a first advantageous embodiment, molybdenum or a molybdenum-containing alloy is used as radiation-absorbing material. Molybdenum has the atomic number 42 and is therefore well-suited to the absorption of scattered radiation. However, the fact that molybdenum has, at approximately 2600° C., a significantly lower melting point in comparison with other materials suitable for the construction of a collimator can be considered a particular advantage. This simplifies the production complexity. By way of example, lower laser powers are needed in a laser melting method as a result of the lower process temperatures. Such powers can be achieved by comparatively cost-effective lasers.

The fact that molybdenum has a comparatively low thermal conductivity of 139 W/(m·K) with respect to the other materials can be considered a further advantage. As a result of this, particularly thin wall structures of the 2D collimator element can be produced because the heat introduced by the laser does not propagate that quickly toward the side. Structures of the collimator element can thus be constructed with high precision in a very targeted fashion.

Moreover, due to the comparatively low density of 10.28 g/cm³, the component mass also reduces correspondingly in the case of the same installation size. This is particularly advantageous if such 2D collimator elements are used in the construction of a radiation detector in a computed tomography scanner. This is because the maximum centrifugal forces occurring during the rotation of the gantry, which have to be absorbed by corresponding support or holding structures provided for the collimator, are thereby reduced. Hence, the complexity for producing a mechanical connection between the collimator and the radiation detector is reduced.

Moreover, molybdenum is comparatively inexpensive and readily available, and so the cost expenditure for a collimator is reduced by the use of molybdenum.

The aforementioned advantages likewise hold true if a molybdenum-containing alloy is used as radiation-absorbing material. The additional alloying elements allow optimum targeted adaption to the present situation of, in particular, the mechanical properties and physical properties, for example the absorption properties with respect to X-ray radiation.

Furthermore, tungsten, tantalum or an alloy with tungsten and/or tantalum as components is preferably used as radiation-absorbing material. Like molybdenum, these metals can likewise be used in laser melting without the use of an additional binding agent, and so the metal filler content of the webs is almost 100% and a very effective collimation is thereby obtained.

In an advantageous refinement of at least one embodiment of the invention, the width of the webs with φ- and/or with z-alignment is, starting from the upper side, designed to be increasingly wider in the direction of the lower side of the 2D collimator element, and so the stability of the cell-shaped structure is increased. More particularly, the width can be selected according to the expected local maximum centrifugal forces in the 2D collimator element, which forces can occur during the rotational operation when using the 2D collimator element in a computed tomography scanner.

Moreover, the webs with φ- and/or with z-alignment are designed with an incline with respect to the base area of the collimator element that increases from the center in the direction of the sides of said 2D collimator element. In particular, the angles of inclination of the webs with φ- and/or with z-alignment are in this case selected with respect to the base area of the collimator element such that the webs are, in an assembled state, aligned in the direction of a focus of an X-ray source. This means that the webs in the central region of the 2D collimator element have a vertical arrangement such that they respectively extend parallel to the direction of propagation of the beam fan. As the distance to the center increases, the webs are inclined more and more strongly inwardly, toward the center of the 2D collimator element. The result of this is that in the edge regions of the 2D collimator element, the distance between two adjacent webs is smaller on the upper side of the 2D collimator element than the distance at the lower side thereof.

It is preferable for a plurality of 2D collimator elements to be assembled in the φ-direction to form a collimator arrangement, in particular for an X-ray detector of a computed tomography scanner. Thus, arbitrarily large collimator arrangements can be produced, which satisfy the requirements for covering the entire X-ray detector in both the φ- and z-directions. Depending on the configuration of the 2D collimator element, only one edge region in each direction is provided with webs, and so the radiation channels are designed to be open in one edge region of the 2D collimator. The open radiation channels are only closed in the assembled collimator arrangement by a web of an adjacent 2D collimator element, and so each individual pixel of the X-ray detector is bounded on four sides by webs of the collimator arrangement. However, it is also possible for two or more pixels to be situated between two opposing webs, particularly in the z-direction and also as a function of the z-position in further example embodiments. Thus, more than only one pixel is surrounded by the radiation channels in these cases.

In an advantageous refinement of at least one embodiment of the invention, the plurality of 2D collimator elements are integrally connected to one another, more particularly they are adhesively bonded to one another, in at least the z-direction. The integral connection is brought about between the ends of the webs in the attachment direction of the first 2D collimator element and the one web wall of the second 2D collimator element, which web wall runs parallel thereto. In the case of 2D collimator elements with webs formed on both sides, webs of two adjoining 2D collimator elements oriented to one another are adhesively bonded together.

In an advantageous refinement of at least one embodiment of the invention, holding and/or adjustment elements are formed for holding or adjusting the 2D collimator element, and so there is no need for an additional production process for attaching such elements.

This allows the 2D collimator elements to be advantageously connected to one another in an interlocking and simple fashion in at least one of the two directions.

According to at least one embodiment of the invention, a 2D collimator element produced according to one of the aforementioned embodiments of the method is disclosed.

### BRIEF DESCRIPTION OF THE DRAWINGS

Example embodiments of the invention and further advantageous refinements of the invention as per the dependent claims are illustrated in the following schematic drawings, in which

FIG. 1 shows a schematic illustration of a computed tomography scanner,

FIG. 2 shows a perspective side view of a 2D collimator element,

FIG. 3 shows a front view of a section of a 2D collimator element, and

FIG. 4 shows a flowchart for a production method for the 2D collimator element.

Parts that have the same effect are provided in the figures with the same reference signs.

### DETAILED DESCRIPTION OF THE EXAMPLE EMBODIMENTS

Various example embodiments will now be described more fully with reference to the accompanying drawings in which only some example embodiments are shown. Specific structural and functional details disclosed herein are merely representative for purposes of describing example embodiments. The present invention, however, may be embodied in many alternate forms and should not be construed as limited to only the example embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

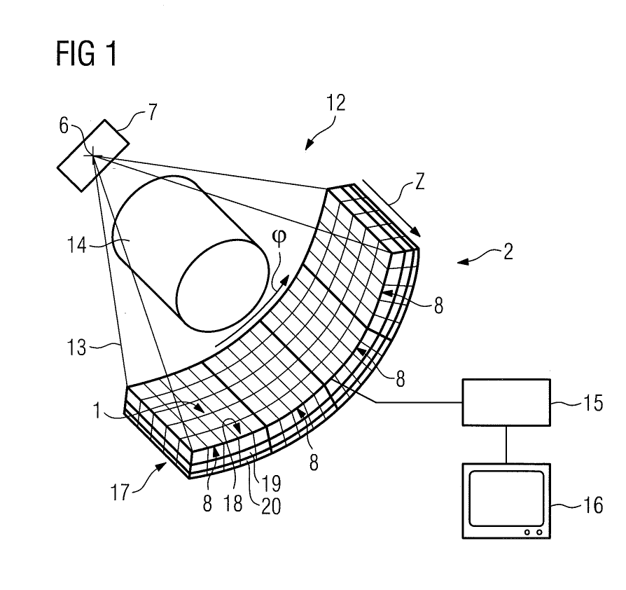

FIG. 1 shows a computed tomography scanner 12, which comprises a radiation source in the form of an X-ray tube 7, from the focus 6 of which an X-ray beam fan 13 is emitted. The X-ray beam fan 13 penetrates an object 14 to be examined or a patient, and impinges on a radiation detector, in this case an X-ray detector 2.

The X-ray tube 7 and the X-ray detector 2 are arranged opposite to one another on a gantry (not shown here) of the computed tomography scanner 12, which gantry can rotate in a φ-direction about a system axis z (=patient axis) of the computed tomography scanner 12. Thus, the φ-direction constitutes the circumferential direction of the gantry and the z-direction constitutes the longitudinal direction of the object 14 to be examined.

During the operation of the computed tomography scanner 12, the X-ray tube 7 arranged on the gantry and the X-ray detector 2 rotate around the object 14, wherein X-ray recordings of the object 14 are obtained from various projection directions. For each X-ray projection, X-ray radiation that has passed through the object 14 and is thereby attenuated impinges on the X-ray detector 2. In the process, the X-ray detector 2 generates signals that correspond to the intensity of the incident X-ray radiation. The signals registered by the X-ray detector 2 are subsequently used by an evaluation unit 15 to calculate one or more two- or three-dimensional images of the object 14 in a known fashion, which images can be displayed on a display unit 16.

The X-ray detector 2 has a plurality of detector modules 17—four in the present example—that are arranged next to one another in the φ-direction, with only one thereof being provided with a reference sign. Each of the detector modules 17 comprises detector elements 18 lined-up in rows in the z-direction and in columns in the φ-direction for converting the X-ray radiation into signals, with likewise only one of the detector elements being provided with a reference sign for reasons of clarity. By way of example, the conversion is brought about by way of a photodiode 20 optically coupled to a scintillator 19 or by way of a direct-conversion semiconductor. In this example embodiment, the detector elements 18 are designed in the style of a scintillation detector.

The primary radiation emitted by the focus 6 of the X-ray tube 7 is scattered, inter alia in the object 14, in different spatial directions. This so-called secondary radiation generates signals in the detector elements 18 that cannot be distinguished from the signals from primary radiation required for the image reconstruction. Therefore, without further measures, the secondary radiation would lead to misinterpretations of the detected radiation and thus to a significant deterioration in the quality of the images obtained by way of the computed tomography scanner 12. In order to limit the influence of the secondary radiation, a collimator arrangement 8 is used to pass substantially only the component of the X-ray radiation emanating from the focus 6, i.e. the primary radiation component, in an unhindered fashion onto the X-ray detector 2, while the secondary radiation is, in the ideal case, completely absorbed.

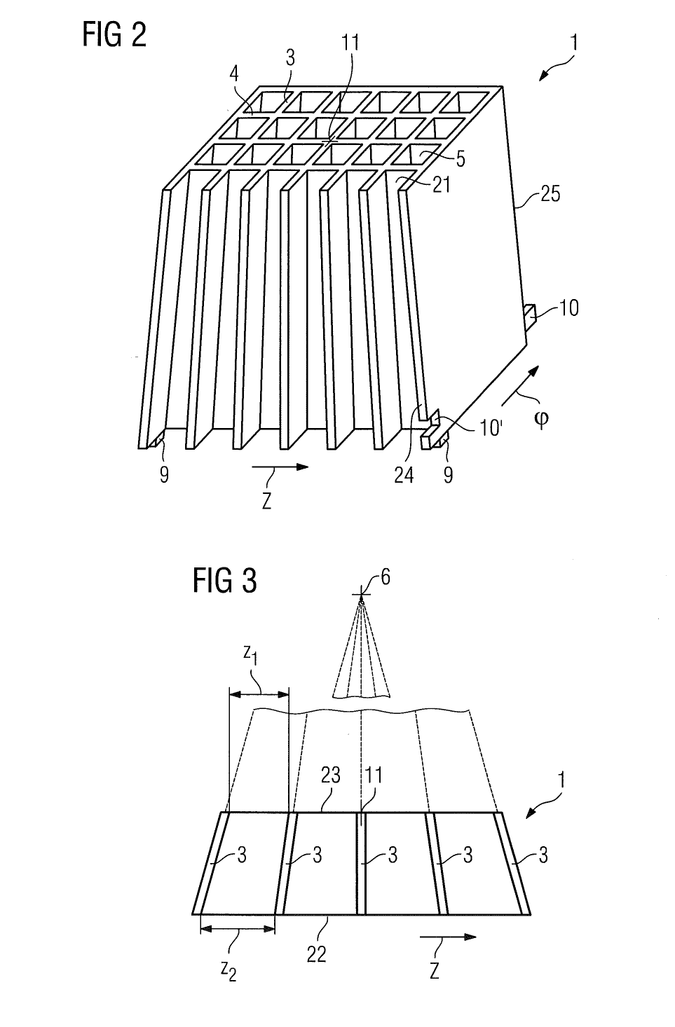

In accordance with the grouping of the detector modules 17, the collimator arrangement 8 comprises a plurality of 2D collimator elements 1—four in this example embodiment—arranged in succession in the φ-direction, with one of the 2D collimator elements 1 being shown in FIG. 2 in a perspective side view. The 2D collimator element 1 is formed integrally from webs 3, 4, made of a radiation-absorbing material, that are aligned along a φ- and a z-direction. Hence, the webs 3, 4 form a cell-shaped structure with laterally enclosed radiation channels 5, with only one radiation channel being provided with a reference sign. It is only in the front edge region of the 2D collimator element 1 that the web 4 aligned in the z-direction is missing, and so the channels 21 present there are open to the side. In the assembled state, the channels 21 in this edge region are closed off by a web 4 running in the z-direction that is part of the adjacently adjoining 2D collimator element 1. Hence, radiation channels 5 can also be formed in the interface region between two 2D collimator elements 1, which radiation channels have a web 4 with a single web width in the boundary region.

The webs 3, 4 are produced with tungsten as radiation-absorbing material. However, it would likewise be feasible to use tantalum, an alloy with tungsten and/or tantalum components or other metals instead of tungsten.

So that substantially only the primary radiation emanating from the focus 6 impinges on the detector elements 18, all webs 4 in the assembled state are always aligned with the focus 6 of the X-ray tube 7. Accordingly, the webs in the center 11 of the 2D collimator element 1 are arranged vertically. As the distance from the center 11 increases they are, as is also shown in FIG. 3 in a front view of a 2D collimator element 1, inclined ever more strongly inwardly with respect to the vertical direction and toward the center 11 of the 2D collimator element. In the example embodiment illustrated in FIG. 2, only the webs 4 aligned in the φ-direction have an incline. For the purpose of effective collimation of the X-ray radiation, the webs 3 with z-alignment are likewise designed with an incline as the distance from the center 11 increases. The effect of this is that in the edge regions of the 2D collimator element 1, the distance z₁ between two adjacent webs on the upper side 23 of the 2D collimator element is smaller than the distance z₂ at the base area 22 thereof.

The collimator arrangement 8 in FIG. 1 is produced by a plurality of 2D collimator elements 1 being positioned next to one another in the φ-direction and being fixedly connected to one another, more particularly being fixedly adhesively bonded to one another. In order to increase the height of the collimator arrangement 8, it is also possible for a plurality of 2D collimator elements 1 to be arranged one above the other. If the width of the 2D collimator elements 1 in the z-direction does not correspond to the width of the X-ray detector 2, it is also possible for two or more 2D collimator elements 1 with suitably chosen widths to be positioned in succession in the z-direction, and so the detector surface is completely covered by the collimator arrangement 8 in the z-direction. In order to align the 2D collimator elements 1 with respect to one another, a web running in the φ-direction has an adjustment element 10′ in the form of a groove on the front edge 24 of the web and a pin 10 fitting into the groove on the rear edge 25 of the web, and so 2D collimator elements 1 can be connected in an interlocking fashion. Moreover, the two outer webs 3 have pins that can be connected in an interlocking fashion to corresponding grooves in the scintillator 19. The pins satisfy the function of a holding element 10 for holding the 2D collimator element 1 on the scintillator 19.

The 2D collimator elements 1 are produced by way of a rapid manufacturing technique—by way of selective laser melting (SLM) in this example embodiment. The 2D collimator element 1 is constructed in three dimensions according to the layer-construction principle by irradiating individual layers using a laser, for example a fiber laser, which has a laser power of approximately 100 to 200 Watt. As a result of the good focusability of the laser radiation, selectively small areas can be sintered and very fine webs 3, 4 of the order of a few hundred μm can be produced.

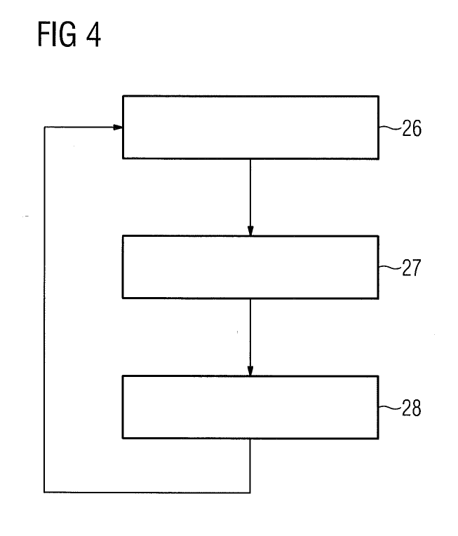

Here, the production method comprises the following steps illustrated in FIG. 4:
a) (26) First of all, a thin layer of the powdery metal, or rather molybdenum, tungsten or tantalum, is applied in a surface covering fashion on a construction platform by way of a doctor blade or roller.
b) (27) The layer is subsequently irradiated by the laser beam at the positions of the webs 3, 4 in the (p- and z-direction according to the present layer data. The energy supplied by the laser is in the process absorbed by the powder and this leads to locally delimited sintering or fusing of the particles with a reduction in the overall surface.
c) (28) After the irradiation process, the construction platform is lowered by a small amount and a new layer is drawn on as per step a).

This procedure is carried out until crossing webs 3, 4 with the required inclinations and heights necessary for effective collimation have been formed.

However, the use of the production method and the 2D collimator element 1 is not only limited to the X-ray beam diagnostics field of application, but can also be used in imaging systems using gamma radiation or radiation with a different wavelength spectrum.

In this context, reference is explicitly made to the fact that when dimensioned appropriately the 2D collimator element can cover the entire active surface of a radiation detector. In other words, this means that the 2D collimator element need not be a segment of the collimator but can form the collimator as such when dimensioned appropriately.

In summary: At least one embodiment of the invention relates to a method for producing a 2D collimator element 1 for a radiation detector 2, in which crossing webs 3, 4 made of a radiation-absorbing material are formed, layer-by-layer, by way of a rapid manufacturing technique, which webs are aligned along a φ- and a z-direction and form a cell-shaped structure with laterally enclosed radiation channels 5, at least in the inner region of the 2D collimator element 1. At least one embodiment of the invention moreover relates to a 2D collimator element 1 for a radiation detector 2 that has such a layered construction. This allows the provision of a very precise and rigid collimator arrangement 8 which, at the same time, has a high collimation effect.

The patent claims filed with the application are formulation proposals without prejudice for obtaining more extensive patent protection. The applicant reserves the right to claim even further combinations of features previously disclosed only in the description and/or drawings.

The example embodiment or each example embodiment should not be understood as a restriction of the invention. Rather, numerous variations and modifications are possible in the context of the present disclosure, in particular those variants and combinations which can be inferred by the person skilled in the art with regard to achieving the object for example by combination or modification of individual features or elements or method steps that are described in connection with the general or specific part of the description and are contained in the claims and/or the drawings, and, by way of combinable features, lead to a new subject matter or to new method steps or sequences of method steps, including insofar as they concern production, testing and operating methods.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

Further, elements and/or features of different example embodiments may be combined with each other and/or substituted for each other within the scope of this disclosure and appended claims.

Still further, any one of the above-described and other example features of the present invention may be embodied in the form of an apparatus, method, system, computer program, computer readable medium and computer program product. For example, of the aforementioned methods may be embodied in the form of a system or device, including, but not limited to, any of the structure for performing the methodology illustrated in the drawings.

Even further, any of the aforementioned methods may be embodied in the form of a program. The program may be stored on a computer readable medium and is adapted to perform any one of the aforementioned methods when run on a computer device (a device including a processor). Thus, the storage medium or computer readable medium, is adapted to store information and is adapted to interact with a data processing facility or computer device to execute the program of any of the above mentioned embodiments and/or to perform the method of any of the above mentioned embodiments.

The computer readable medium or storage medium may be a built-in medium installed inside a computer device main body or a removable medium arranged so that it can be separated from the computer device main body. Examples of the built-in medium include, but are not limited to, rewriteable non-volatile memories, such as ROMs and flash memories, and hard disks. Examples of the removable medium include, but are not limited to, optical storage media such as CD-ROMs and DVDs; magneto-optical storage media, such as MOs; magnetism storage media, including but not limited to floppy disks (trademark), cassette tapes, and removable hard disks; media with a built-in rewriteable non-volatile memory, including but not limited to memory cards; and media with a built-in ROM, including but not limited to ROM cassettes; etc. Furthermore, various information regarding stored images, for example, property information, may be stored in any other form, or it may be provided in other ways.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A method for producing a 2D collimator element for a radiation detector, comprising:
forming crossing webs, made of a radiation-absorbing material, layer-by-layer by way of a rapid manufacturing technique, the webs being aligned along a φ-direction and a z-direction and forming a cell-shaped structure with laterally enclosed radiation channels, at least in an inner region of the 2D collimator element.

2. The method as claimed in claim 1, wherein selective laser melting is used as the rapid manufacturing technique.

3. The method as claimed in claim 1, wherein molybdenum or a molybdenum-containing alloy is used as radiation-absorbing material.

4. The method as claimed in claim 1, wherein tungsten, tantalum or an alloy comprising at least one of tungsten and tantalum as an alloying element is used as radiation absorbing material.

5. The method as claimed in claim 1, wherein the webs with at least one of φ-alignment and with z-alignment are designed with an incline with respect to the base area of the collimator element that increases from the center in a direction of the sides of said 2D collimator element.

6. The method as claimed in claim 5, wherein angles of inclination of the webs with φ-alignment and with z-alignment are selected with respect to the base area of the 2D collimator element such that the webs are, in an assembled state, aligned in the direction of a focus of a radiation source.

7. The method as claimed in claim 1, wherein the width of the webs with φ-alignment and with z-alignment is, starting from the upper side, designed to become increasingly wider in a direction of a lower side of the 2D collimator element.

8. The method as claimed in claim 1, wherein a plurality of 2D collimator elements are produced and assembled in at least one of the φ-direction and z-direction to form a collimator arrangement for the radiation detector.

9. The method as claimed in claim 8, wherein the plurality of 2D collimator elements are integrally connected to one another in at least the z-direction.

10. The method as claimed in claim 8, wherein the plurality of 2D collimator elements are connected to one another in an interlocking fashion in at least one of the two directions.

11. The method as claimed in claim 1, wherein, in addition to the webs, at least one of holding and adjustment elements are also formed for at least one of respectively holding and adjusting the 2D collimator element.

12. A 2D collimator element for a radiation detector, comprising:
a crossing web structure, made of a radiation-absorbing material as a product of a production method according to a rapid manufacturing technique, the crossing web structure being of an integral design and including a cell-shaped structure with laterally enclosed radiation channels, wherein the webs are built up from the radiation-absorbing material, layer-by-layer, along two different directions.

13. The 2D collimator element as claimed in claim 12, wherein selective laser melting is the rapid manufacturing technique.

14. The 2D collimator element as claimed in claim 12, wherein molybdenum or a molybdenum-containing alloy is the radiation-absorbing material.

15. The 2D collimator element as claimed in claim 12, wherein at least one of tungsten, tantalum or an alloy comprising at least one of tungsten and tantalum as alloying element is the radiation-absorbing material.

16. The 2D collimator element as claimed in claim 12, wherein the two directions are the with φ-direction and the z-direction, and wherein the webs with at least one of φ-alignment and with z-alignment are designed with an incline with respect to a base area of the collimator element that increases from a center in the direction of sides of the 2D collimator element.

17. The 2D collimator element as claimed in claim 16, wherein the angles of inclination of the webs with at least one of the φ-alignment and with z-alignment are selected with respect to the base area of the 2D collimator element such that the webs are, in an assembled state, aligned in a direction of a focus of a radiation source.

18. The 2D collimator element as claimed in claim 12, wherein the two directions are the with φ-direction and the z-direction, and wherein a width of the webs with at least one of φ-alignment and with z-alignment, starting from an upper side, increases in a direction of the lower side of the 2D collimator element.

19. The 2D collimator element as claimed in claim 12, wherein the two directions are the with φ-direction and the z-direction, and wherein a plurality of 2D collimator elements are assembled in at least one of the φ-direction and the z-direction to form a collimator arrangement for the radiation detector.

20. The 2D collimator element as claimed in claim 19, wherein the plurality of 2D collimator elements are integrally connected to one another in at least the z-direction.

21. The 2D collimator element as claimed in claim 19, wherein the plurality of 2D collimator elements are connected to one another in an interlocking fashion in at least one of the two directions.

22. The 2D collimator element as claimed in claim 12, wherein, in addition to the webs, at least one of holding and adjustment elements are also provided for at least one of holding and adjusting the 2D collimator element.

23. The method as claimed in claim 2, wherein molybdenum or a molybdenum-containing alloy is used as radiation-absorbing material.

24. The method as claimed in claim 2, wherein tungsten, tantalum or an alloy comprising at least one of tungsten and tantalum as an alloying element is used as radiation-absorbing material.

25. The 2D collimator element as claimed in claim 13, wherein molybdenum or a molybdenum-containing alloy is the radiation-absorbing material.

26. The 2D collimator element as claimed in claim 13, wherein at least one of tungsten, tantalum or an alloy comprising at least one of tungsten and tantalum as alloying element is the radiation-absorbing material.

27. A radiation detector comprising the 2D collimator element as claimed in claim 12.
